(19) United States
(12) Patent Application Publication
(10) Pub. No.: US 2025/0151288 A1
(43) Pub. Date: May 8, 2025

(54) MEMORY DEVICE COMPRISING RRAM MEMORY CELLS WITH OPTIMIZED ACTIVE AREA

(71) Applicant: Commissariat à l'Énergie Atomique et aux Énergies Alternatives, Paris (FR)

(72) Inventor: Gabriel Pares, Grenoble (FR)

(73) Assignee: Commissariat à l'Énergie Atomique et aux Énergies Alternatives, Paris (FR)

(21) Appl. No.: 18/937,470

(22) Filed: Nov. 5, 2024

(30) Foreign Application Priority Data
Nov. 6, 2023 (FR) 2312005

(51) Int. Cl. H10B 63/00

(52) U.S. Cl. CPC H10B 63/80

(57) ABSTRACT

A memory device including, in a first metallization level: first electrical interconnection lines parallel to one another, metal portions parallel to one another and each electrically coupling two neighboring first electrical interconnection lines, and wherein a memory element of OxRAM or CBRAM type is arranged at each interface between one of the metal portions and one of the first electrical interconnection lines, and each memory element includes a first electrode arranged against said one of the first electrical interconnection lines, a second electrode arranged against said one of the metal portions, and a memory layer arranged between the first and second electrodes.

### TECHNICAL FIELD

The present disclosure generally concerns the field of resistive-type non-volatile memories (RRAM or ReRAM) based on oxide (OxRAM) or on metal electrolyte (CBRAM).

### PRIOR ART

The main block of a memory is formed of an array of memory cells, or “bit cells”. Each memory cell comprises at least one selection transistor and at least one memory element performing the storage of the information for the memory cell. The memory cells are electrically coupled to electrical connection elements formed by stacked metal levels, or metallization levels, corresponding to the circuit BEOL (Back End Of Line).

In an OxRAM-type memory, each memory cell is generally formed by a vertical mesa, or island, structure in which an oxide portion is arranged between upper and lower electrodes in the form of a vertical stack. P. Polakowski et al.'s document, “Ferroelectric deep trench capacitors based on Al:HfO2 for 3D nonvolatile memory applications”, 2014 IEEE 6th International Memory Workshop (IMW), Taipei, Taiwan, 2014, pp. 1-4, describes such a configuration.

Other memory cell architectures have been considered, for example in the form of a cylindrical 3D structure as described in G. Piccolboni et al.'s document, “Investigation of the potentialities of Vertical Resistive RAM (VRRAM) for neuromorphic applications,” 2015 IEEE International Electron Devices Meeting (IEDM), Washington, DC, USA, 2015, pp. 17.2.1-17.2.4.

In an OxRAM-type memory element, the active surface area, which corresponds to the surface area of contact between the oxide portion and the electrodes, determines a great part of the electrical characteristics of the memory element. For the different previously-mentioned vertical architectures of a memory element, this active area is however limited by the total surface area available for the cell in the plane of the memory cell array. A decrease in the total surface area available for the memory cell is then accompanied by a decrease in the active surface area of the memory cell, which generates a number of problems: increase in the voltage allowing the storage of information into the memory cell, increase in the variability of the electrical parameters (current, voltage) of the memory elements, loss of efficiency.

Similar problems also arise for CBRAM-type memories.

### SUMMARY OF THE INVENTION

There thus exists a need to provide a resistive memory structure allowing a decrease in the surface area of occupancy of the memory cells while limiting or eliminating the previously-mentioned problems.

An embodiment provides a solution to all or part of the disadvantages of known solutions and provides a memory device comprising, in a first metallization level:
first electrical interconnection lines parallel to one another,
metal portions parallel to one another, and each electrically coupling two adjacent first electrical interconnection lines,
and wherein a memory element of OxRAM or CBRAM type is arranged at each interface between one of the metal portions and one of the first electrical interconnection lines, and each memory element comprises a first electrode arranged against said one of the first electrical interconnection lines, a second electrode arranged against said one of the metal portions, and a memory layer arranged between the first and second electrodes.

According to a specific embodiment, the first electrical interconnection lines, the metal portions, and the memory elements are arranged, or formed, in a same longitudinal plane parallel to a substrate of the memory device.

According to a specific embodiment, each memory element further comprises a portion of getter material arranged between the memory layer and one of the first and second electrodes.

According to a specific embodiment, the memory device further comprises, in a second metallization level parallel to the first metallization level, second electrical interconnection lines parallel to one another and electrically coupled to the metal portions or to the first electrical interconnection lines.

According to a specific embodiment, the memory device further comprises first electrically-conductive vias electrically coupling the second electrical interconnection lines to the metal portions or to the first electrical interconnection lines.

According to a specific embodiment, when the second electrical interconnection lines are electrically coupled to the metal portions, the first electrical interconnection lines are source lines of the memory device and the second electrical interconnection lines are bit lines of the memory device.

According to a specific embodiment, the first metallization level is arranged between the second metallization level and the substrate of the memory device.

According to a specific embodiment, the substrate comprises a semiconductor layer having transistors formed therein, one of the source or drain electrodes of each of the transistors is electrically coupled to one of the first electrical interconnection lines or to one of the metal portions by a second electrically-conductive via extending between the semiconductor layer and said one of the first electrical interconnection lines or between the semiconductor layer and said one of the metal portions.

According to a specific embodiment, the device comprises, in a third metallization level parallel to the first and second metallization levels and such that the first metallization level is arranged between the second and third metallization levels, third electrical interconnection lines parallel to one another and perpendicular to the first electrical interconnection lines, and the third electrical interconnection lines are electrically coupled to the gates of the transistors.

According to a specific embodiment, each of the two adjacent first electrical interconnection lines is electrically coupled to memory elements which are electrically coupled to different second electrical interconnection lines.

According to a specific embodiment, the first electrical interconnection lines extend in a plane perpendicular to surfaces of larger dimensions of the memory layer and of the first and second electrodes.

According to a specific embodiment, there is provided a method of forming a memory device, comprising at least:
forming, in a first metallization level, of first electrical interconnection lines parallel to one another, and of metal portions parallel to one another and each electrically coupling two neighboring first electrical interconnection lines,
forming, at each interface between one of the metal portions and one of the first electrical interconnection lines, of a memory element of OxRAM or CBRAM type comprising a first electrode arranged against said one of the first electrical interconnection lines, a second electrode arranged against said one of the metal portions, and a memory layer arranged between the first and second electrodes.

According to a specific embodiment, the first electrical interconnection lines, the metal portions, and the memory elements are formed by implementing the following steps:
etching, into a first dielectric layer, first trenches defining locations for the first electrical interconnection lines,
deposition of at least one first metallic material into the first trenches, forming the first electrodes of the memory elements, and of at least one second metallic material forming the first electrical interconnection lines,
etching, into the first dielectric layer, of first holes defining locations for the metal portions and the memory elements,
successive depositions of a plurality of materials into the first holes, forming the memory elements and the metal portions.

According to a specific embodiment, the method further comprises, after the forming of the first electrical interconnection lines, of the metal portions, and of the memory elements:
deposition of at least a second dielectric layer on the first electrical interconnection lines, the metal portions, and the memory elements,
etching, through a first part of the thickness of the second dielectric layer, of second trenches parallel to one another and defining locations for second electrical interconnection lines,
etching, through a second part of the thickness of the second dielectric layer, under the second trenches and vertically in line with the metal portions or the first electrical interconnection lines, second holes defining locations for first electrically-conductive vias,
deposition of at least one other metallic material into the second holes and into the second trenches, forming the second electrical interconnection lines and the first electrically-conductive vias electrically coupling one of the second electrical interconnection lines to the metal portions or to the first electrical interconnection lines.

According to a specific embodiment, the method further comprises, prior to the forming of the first electrical interconnection lines, metal portions and memory elements, the forming, from a semiconductor layer of a substrate, of transistors, one of the source or drain electrodes of each of the transistors being electrically coupled to one of the first electrical interconnection lines or to one of the metal portions by a second electrically-conductive via extending between the semiconductor layer and said one of the first electrical interconnection lines or between the semiconductor layer and said one of the metal portions.

According to a specific embodiment, the forming of the transistors includes the forming of gates electrically coupled to third electrical interconnection lines parallel to one another and perpendicular to the first electrical interconnection lines.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows a portion of an example of a memory device;

FIG. 2 schematically shows a memory cell of a memory device according to a specific embodiment;

FIG. 3 schematically shows the memory elements of a memory cell of the memory device according to a specific embodiment;

FIG. 4 shows an electrical diagram of a plurality of memory cells of the memory device according to a specific embodiment;

FIG. 5 schematically shows a top view of the layout of two memory cells of the memory device according to a specific embodiment;

FIG. 6 schematically shows a portion of a memory cell array of a memory device according to a specific embodiment;

FIG. 7 shows geometric characteristics of the memory elements of a memory device;

FIG. 8, FIG. 9, FIG. 10, FIG. 11, FIG. 12, and FIG. 13 show part of the steps of a method of forming a memory device.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, different elements (readout circuit, row decoder, column decoder, etc.) of the memory device are not detailed. A detailed design of these elements is within the ability of those skilled in the art using the functional description given hereafter.

In the different drawings, the visible elements are not shown to the same scale with respect to one another, to ease the understanding of these drawings.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

All throughout this document, the terms “first”, “second”, and “third” used to designate and to distinguish the different metallization levels of the device do not presume the order in which they are formed and their layout relative to the substrate of the device. Thus, the “first metallization level” does not necessarily correspond to metallization level M1 of the circuit. Similarly, the “second metallization level” and “third metallization level” do not necessarily correspond to metallization levels M2 and M3 of the circuit.

The following description of resistive memories based on oxide (OxRAM) can be applied in the same way to CBRAM-type resistive memories, by replacing the elements forming these OxRAM memories with their CBRAM memory equivalents, namely the lower and upper electrodes respectively by a chemically-inert electrode and a chemically-active electrode, and the resistive layer by a solid electrolyte.

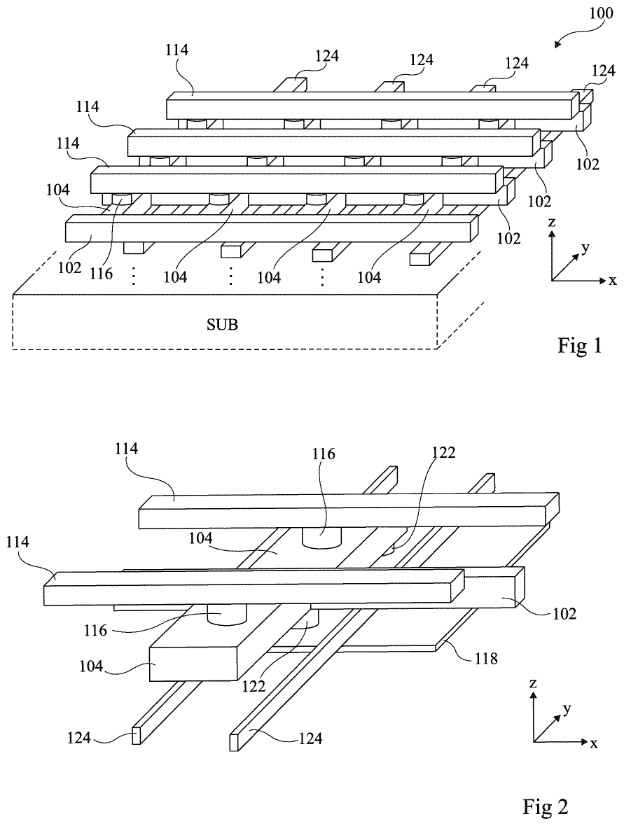

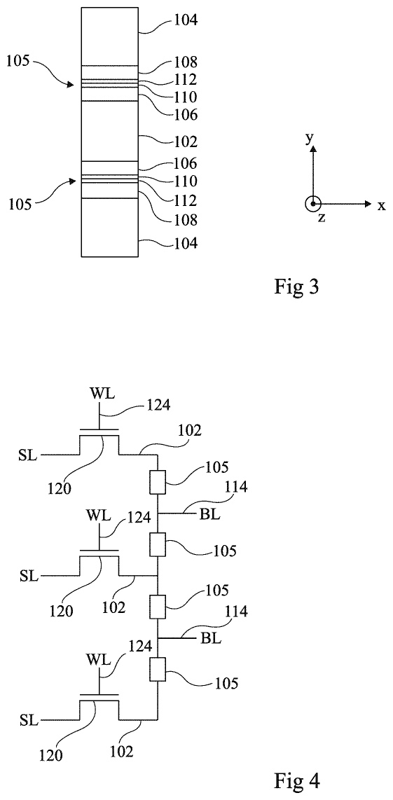

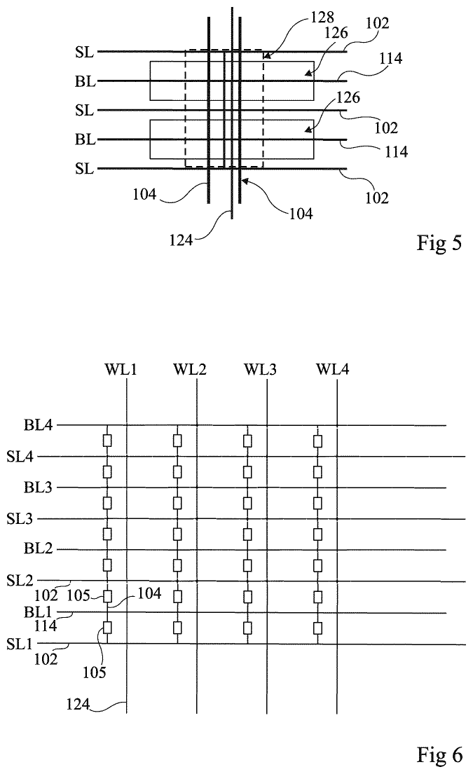

An example of a memory device 100 according to a specific embodiment is described hereafter in relation with FIGS. 1 to 5. FIG. 1 schematically shows a portion of device 100. FIG. 2 schematically shows a memory cell of device 100. FIG. 3 schematically shows the memory elements of a memory cell of device 100. FIG. 4 shows an electrical diagram of a plurality of memory cells of device 100. FIG. 5 schematically shows a top view of the layout of two memory cells of device 100.

Memory device 100 comprises an array of memory cells extending in a plane parallel to the (X, Y) plane shown in FIG. 1. Device 100 is, for example, implemented in the form of an integrated circuit comprising a substrate SUB on top of and/or inside of which components, including the memory cell transistors, are formed. The circuit also comprises a plurality of metallization levels, or “metal layers”, formed above substrate SUB, forming the circuit BEOL and in which the memory elements of the memory cells are formed.

Device 100 comprises, in a first metallization level corresponding, for example, to metallization level M4 of the circuit, first electrical interconnection lines 102 parallel to one another (parallel to the X axis visible in FIG. 1). According to an example, the first lines 102 comprise at least one of the following metallic materials: tungsten, copper, cobalt. Further, the first lines 102 are formed in a dielectric layer not visible on FIG. 1, and for example comprising SiO₂. The thickness (dimension parallel to the Z axis) of the first lines 102 is, for example, in the range from 50 nm to 500 nm. Each of the first lines 102 may be common to all the memory cells arranged on a same line of the array of memory cells.

Device 100 also comprises, in the first metallization level, metal portions 104 parallel to one another, each electrically coupling two neighboring first lines 102. In the example of FIG. 1, each of metal portions 104 extends between two neighboring first lines 102, parallel to the Y axis. According to an embodiment, metal portions 104 comprise at least one of the following metallic materials: copper, tungsten, cobalt. Metal portions 104 are formed in the same dielectric layer as that in which the first lines 102 are formed. The thickness of metal portions 104 is here similar to that of the first lines 102.

In device 100, an OxRAM-type memory element 105 is arranged at each interface of one of the metal portions 104 and of one of the first lines 102. Two examples of these memory elements 105 can be seen in FIG. 3.

Each of the memory elements 105 comprises a first electrode 106 arranged against one of the first lines 102, and a second electrode 108 arranged against one of metal portions 104. According to an embodiment, the first and second electrodes 106, 108 comprise, for example, TiN, which has the advantage of being a chemically-stable material providing an electro-chemical neutrality to electrodes 106, 108. As a variant, the first and second electrodes 106, 108 may comprise TaN or WN.

Each of the memory elements 105 also comprises a memory layer 110 arranged between the first and second electrodes 106, 108, and in which the storage of the information of memory element 105 is intended to be performed. In the case of an OxRAM memory element 105, memory layer 110 corresponds to a resistive layer, for example an oxide portion. According to an example, oxide portion 110 comprises HfO₂.

In the described specific embodiment, each memory element 105 further comprises a portion of getter material 112 arranged between memory layer 110 and one of the first and second electrodes 106, 108. In the example of FIG. 3, for each memory element 105, portion 112 is arranged between memory layer 110 and the second electrode 108 (that is, the electrode arranged against the metal portion 104 of memory element 105). Portion 112 contributes, this example, to the creation of one or a plurality of electrically-conductive filaments in memory layer 110 during the operation of device 100. According to an example of embodiment, portion 112 comprises titanium, or tantalum, or hafnium, or any other material having an electro-chemical affinity with oxygen.

The dimension along the Z axis of layer 110 and of portion 112 is, for example, similar to the thickness of the first lines 102.

In the above-described example, each memory element 105 is formed by the stack of electrodes 106, 108, of layer 110, and of portion 112, this stack being arranged “horizontally”, that is, extending between one of the first lines 102 and one of portions 104 along a direction belonging to the plane in which the first lines 102 and portions 104 are located. In the described example, the direction of the stack (parallel to the Y axis in FIGS. 1 to 3) forming each memory element 105 is perpendicular to the direction along which the first lines 102 extend.

In the described example, the first electrical interconnection lines 102, the metal portions (104), and the memory elements 105 are arranged in the same longitudinal plane parallel to the substrate SUB of memory device 100.

In the described specific embodiment, the first lines 102 extend in a plane perpendicular to surfaces of larger dimensions of memory layer 110 and of the first and second electrodes 106, 108.

Further, in each memory element 105, the active surface area is defined by the dimension along the X axis of metal portion 104 and the thickness of the first line 102 and of metal portion 104. Thus, a decrease in the total surface area of the memory cell in the plane of the memory cell array does not directly impact the active surface area of each memory element 105 and can be compensated for by an increase in the thickness of lines 102 and of portions 104.

In the described embodiment, device 100 also comprises, in a second metallization level, parallel to the first metallization level, of device 100 and corresponding, for example, to metallization level M5 of the circuit, second electrical interconnection lines 114 parallel to one another. In the embodiment described herein, the second electrical interconnection lines 114 are also parallel to the first lines 102.

In the described specific embodiment, device 100 may also comprise electrically-conductive vias 116 extending between the first and second metallization levels of device 100 and each electrically coupling one of the second lines 114 to one of metal portions 104. In another example of embodiment, the second lines 114 may be directly electrically coupled to metal portions 104 without intermediate vias. In another configuration, not shown in the drawings, the second lines 114 may be arranged perpendicular to the first lines 102 and electrically coupled to metal portions 104 by vias 116. The second lines 114 and/or vias 116 comprise one or a plurality of metallic materials for example similar to that or those of metal portions 104. The second lines 114 and vias 116 may be arranged in at least one dielectric layer, not shown in FIGS. 1 to 5, and comprising, for example, SiO₂.

The second lines 114 and vias 116 electrically couple together the portions 104 arranged on the same line of the memory cell array, that is, arranged between the same two first lines 102. Within the memory cells of device 100, the electrical access to the first electrodes 106 of memory elements 105 can thus be achieved via the first lines 102, and the electrical access to the second electrodes 108 can be achieved via the second lines 114, vias 116, and metal portions 104.

Device 100 further comprises a substrate SUB comprising a semiconductor layer 118 having transistors 120 formed therein. The layout of the substrate is such that the first metallization level is arranged between the second metallization level and the substrate.

In the described example of embodiment, transistors 120 correspond to transistors for selecting the memory cells. One of the source or drain electrodes (depending on the conductivity of the transistors) of each of transistors 120 is electrically coupled to one of the first lines 102 by an electrically-conductive via 122 extending between semiconductor layer 118 and this first line 102. The other source or drain electrode is electrically coupled to a control circuit of device 100.

Device 100 comprises, in a third metallization level such that the first metallization level is arranged between the second and third metallization levels (the third metallization level being parallel to the first and second metallization levels), and corresponding for example to the metallization level M3 of the circuit, third electrical interconnection lines 124 parallel to one another and perpendicular at least to the first lines 102 and possibly to the second lines 114 depending on their orientation. In the example shown in FIGS. 1 and 2, the third lines 124 are parallel to the Y axis. The third lines 124 are electrically coupled to the gates of transistors 120 and enable to select for example a column of transistors.

According to an example, the third lines 124 comprise at least one of the following metallic materials: copper, titanium nitride, tantalum nitride. Further, the third lines 124 and vias 122 are formed in a dielectric layer, not shown in FIGS. 1 to 5, and for example comprising SiO₂. The thickness (dimension parallel to the Z axis) of the third lines 124 is, for example, in the range from 40 nm to 500 nm, depending on the CMOS technology node used. Each of the third lines 124 may be common to all the transistors arranged on a same column of the memory cell array.

According to an example of embodiment, the first lines 102 may correspond to source lines of device 100, and the second lines 114 may correspond to bit lines of device 100, or the third lines 124 may form word lines of device 100.

The electrical diagram of a plurality of memory cells of device 100 is shown in FIG. 4. In this embodiment, each of the two neighboring first lines 102 (between which metal portions 102 extend) is electrically coupled to memory elements 105 which are electrically coupled to different second lines 114.

Each memory cell of device 100 thus comprises, in this embodiment, two memory elements 105 coupled to a same bit line, that is, a same second line 114. Further, each source line, that is, each first line 102, is shared by two neighboring memory cells.

FIG. 5 schematically shows a top view (seen in the (X, Y) plane) of the layout of two memory cells of device 100. In this drawing, the regions designated with reference 126 represent portions of the active areas of the transistors 120 of the memory cells of device 100, and the dotted lines designated with reference 128 symbolically delimit the surface areas occupied by the two memory cells visible in this drawing.

Examples of signals for programming memory cells of device 100 are given hereafter in relation with FIG. 6 schematically showing a portion of the array of memory cells, some of which are intended to be programmed by these signals.

The first table below gives examples of the voltages applied on the first lines 102 and the second lines 114 to program to the high state (set) the two memory elements 105 of the memory cell coupled to the first lines 102 having signals SL2 and SL3 applied thereto, and coupled to the second line 114 having signal BL2 applied thereto. Voltage Vset corresponds to the voltage desired across a memory element 105 intended to be programmed to the high state.

TABLE 1

| | BL1 = Vset/2 | BL2 = 0 | BL3 = Vset/2 | BL4 = 0 |
|---|---|---|---|---|
| SL1 = 0 | −Vset/2 | 0 | −Vset/2 | 0 |
| SL2 = Vset | Vset/2 | Vset | Vset/2 | 0 |
| SL3 = Vset | Vset/2 | Vset | Vset/2 | 0 |
| SL4 = 0 | −Vset/2 | 0 | −Vset/2 | 0 |

The second table below gives examples of the voltages applied to the first lines 102 and the second lines 114 to program to the low state (“reset”) these same two memory elements 105 of the memory cell coupled to the first lines 102 having signals SL2 and SL3 applied thereto, and coupled to the second line 114 having signal BL2 applied thereto. Voltage Vreset corresponds to the voltage desired across a memory element 105 intended to be programmed to the low state. During this programming, signals WL2 and WL3, applied to the third lines 124 forming the gates of the transistors 120 which are coupled to the first lines having signals SL2 and SL3 applied thereto, are such that these transistors 120 are in the on state.

TABLE 2

| | BL1 = 0 | BL2 = Vreset | BL3 = 0 | BL4 = 0 |
|---|---|---|---|---|
| SL1 = Vreset/2 | Vreset/2 | −Vreset/2 | −Vreset/2 | 0 |
| SL2 = 0 | 0 | Vreset | 0 | 0 |
| SL3 = 0 | 0 | Vreset | 0 | 0 |
| SL4 = Vreset/2 | Vreset/2 | −Vreset/2 | −Vreset/2 | 0 |

In this specific embodiment, the memory cells of device 100 can be seen as being of type 1T2R. The memory cells of device 100 may be programmed independently of each other by using a suitable crossbar-type read/write protocol.

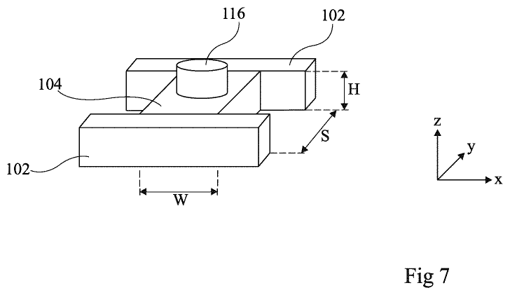

Whatever the example of embodiment of device 100, due to the fact that each memory element 105 is formed by the stacking of electrodes 106, 108, of layer 110, and of portion 112 arranged “horizontally”, that is, extending between one of the first lines 102 and one of the portions 104 in a direction belonging to the plane in which are located the first lines 102 and portions 104, that is, parallel to the plane of the memory cell array of device 100, the value of the voltage enabling to program the memory cells, the variability of the electrical parameters, and the efficiency of the memory cells depend on the dimensions H and W of memory elements 105 in the plane parallel to the (X,Z) plane, shown in FIG. 7, and not on the dimensions S and W in the (X,Y) plane. The decrease in the dimensions of the memory cells in the plane of the memory cell array of device 100 can thus be compensated for by an increase in the dimension perpendicular to this plane (that is, the dimension along the vertical Z axis) and thus avoid for the previously-mentioned problems encountered with memory cells to appear.

In all the examples of embodiment of device 100, the layout of the memory elements at the interfaces between metal portions 104 and the first lines 102 enables to double the surface area of the memory cell for a given bit cell size and thus to double the memory density for a given wafer surface area.

For example, for a memory cell surface area in the order of 0.05 μm², the total active surface area of the memory elements 105 of the cell may be in the order of 0.015 μm², which surface area can be further increased by increasing the thickness H of the first lines 102 and of metal portions 104.

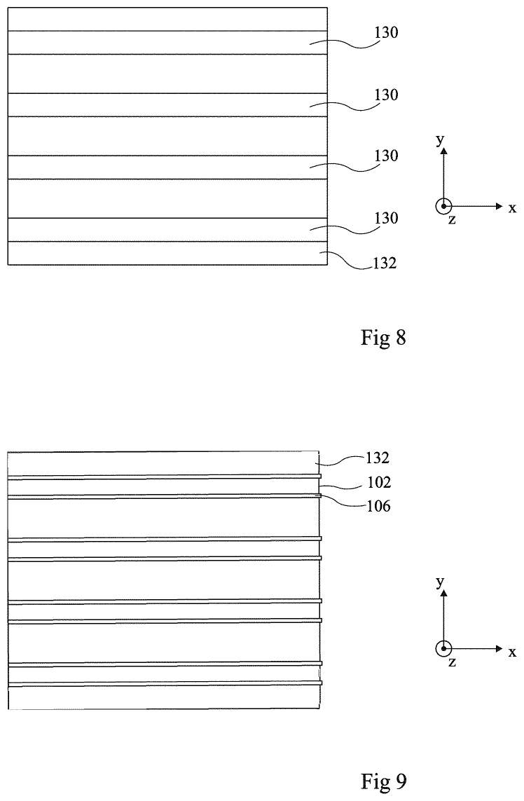

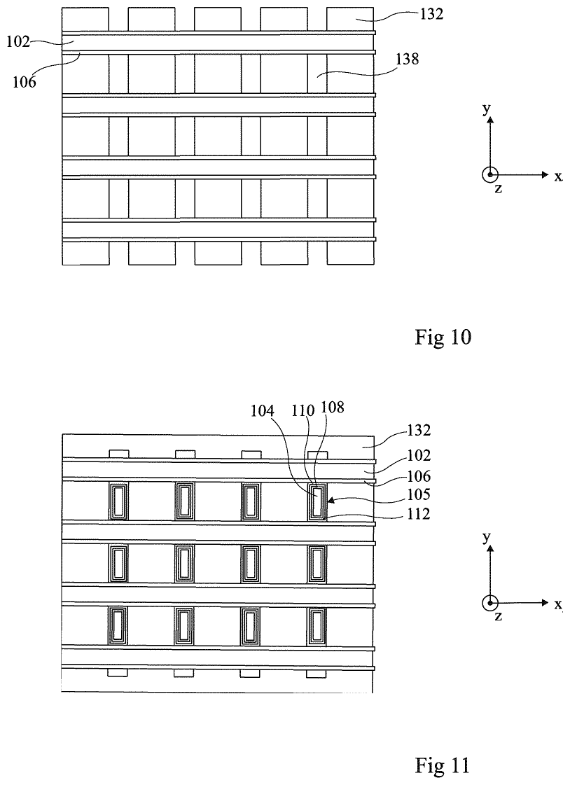

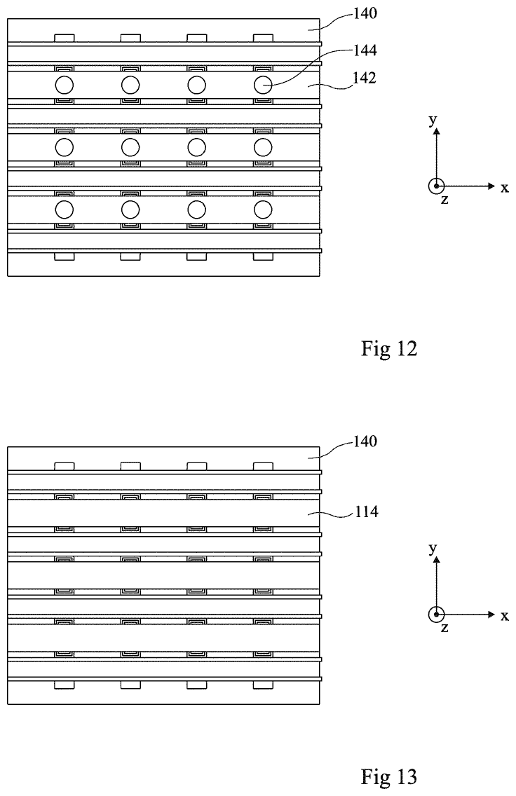

An example of a method of forming a memory device 100 is described hereafter, FIGS. 8 to 13 showing part of these steps.

In this example, the method first comprises the forming, from the semiconductor layer 118 of the substrate, of the different semiconductor components of device 100, and in particular the transistors 120 for selecting the memory cells of device 100.

The different metallization levels intended to form the circuit BEOL are then formed. One of the metallization levels is in particular formed in such a way as to comprise the third lines 124 forming the gates of transistors 120. These third lines 124 are for example formed by the implementation of steps of etching and of deposition through a previously-deposited dielectric layer.

The method is then continued in such a way as to form the first lines 102 parallel to one another, metal portions 104 parallel to one another and each electrically coupling two adjacent first lines 102, and while also forming, at each interface of one of the metal portions 104 and of one of the first lines 102, an OxRAM-type memory element 105 comprising the first and second electrodes 106, 108, memory layer 110, and the portion of getter material 112.

For this purpose, according to an example, first trenches 130 defining locations for the first lines 102 are etched in a first dielectric layer 132 comprising, for example, SiO₂ (see FIG. 8). The thickness (dimension parallel to the Z axis) of the first dielectric layer 132 is, for example, equal to the desired height H of the first lines 102.

A so-called “damascene” method is for example implemented to form the first lines 102 as well as the first electrodes 106. For this purpose, the first trenches 130 are filled with at least one first metallic material intended to form the first electrodes 106 and at least one second metallic material intended to form the first lines 102 (see FIG. 9). According to an example, this filling of the first trenches 130 may comprise a deposition of a TiN layer against the walls of the first trenches 130 and intended to form the first electrodes 106, and then a filling of the remaining volume of the first trenches 130 with tungsten intended to form the first lines 102. The portion(s) of metallic material deposited outside the first trenches 130 can then be removed by implementing a chemical-mechanical planarization (CMP), with a stop on the first dielectric layer 132. As a variant, the first electrodes 106 may be formed by a deposition of a layer of tungsten, cobalt, or copper nitride.

First holes 138 defining locations for metal portions 104 and memory elements 105 are then etched into the first dielectric layer 132 (FIG. 10).

The materials intended to form memory layers 110, the portions of getter material 112, the second electrodes 108, and metal portions 104 are then successively deposited into the first holes 138 (FIG. 11). The portions of these materials deposited outside the first holes 138 may be removed by implementing a CMP with a stop on the first dielectric layer 132.

As an variant of the above example, it is possible for the first electrodes 106 not to be formed by the deposition of a first metal layer into the first trenches 130, but by the deposition of a first metal layer into the first holes 138 implemented before the deposition of the material intended to form memory layers 110.

The method is then carried on in such a way as to form, in a metallization level located above that comprising the first lines 102, the second lines 114, and vias 116.

To achieve this, at least one second dielectric layer 140 is deposited on the first dielectric layer 132, the first lines 102, metal portions 104, and memory elements 105.

A so-called “double damascene” method may be implemented to form the second lines 114 and vias 116.

In this case, second trenches 142 parallel to one another and defining locations for the second lines 114 are then etched through a first part of the thickness of the second dielectric layer 140. Second holes 144 defining locations for vias 116 are then etched through a second part of the thickness of the second dielectric layer 140 and under the second trenches 142, vertically in line with metal portions 104 (FIG. 12).

At least another metallic material is then deposited into the second holes 144 and into the second trenches 142, forming the second lines 114 and the first vias 116 electrically coupling the second lines 114 to metal portions 114 (FIG. 13).

As a variant of the above example, it is possible to first form vias 116 by steps of etching and deposition through a second dielectric layer deposited on the first dielectric layer 132, the first lines 102, metal portions 104, and memory elements 105. The second lines 114 may then be formed by steps of etching and deposition through a third dielectric layer deposited on the second dielectric layer and vias 116.

As a variant, vias 116 may be avoided by directly connecting two by two the second lines 114 and metal portions 104 at each intersection.

As an variant of the previously-described examples of embodiment in which transistors 120 are electrically coupled to the first lines 102 by the second vias 122, it is possible for one of the source or drain electrodes of each of transistors 120 to be electrically coupled to one of metal portions 104 by one of the second vias 122. In this case, each second via 122 may extend between semiconductor layer 118 and one of metal portions 104. Further, in this variant, the second lines 114 forming the bit lines may be arranged perpendicularly to the first lines 102 and be electrically coupled to the first lines 102 possibly by the first vias 116, and the source lines of device 100 may be coupled to metal portions 104.

Various embodiments and variants have been described. Those skilled in the art will understand that certain features of these various embodiments and variants could be combined, and other variants will become apparent to the person skilled in the art.

Finally, the practical implementation of the described embodiments and variants is within the abilities of those skilled in the art, based on the functional indications given above. For example, the specific nature of the implemented deposition and etching steps may be selected in particular according to the material(s) to be deposited or to be etched, as well as the thicknesses of material to be deposited or etched.

1. Memory device comprising a substrate, the memory device comprising, in a first metallization level:
first electrical interconnection lines parallel to one another,
metal portions parallel to one another and each electrically coupling two neighboring first electrical interconnection lines,
wherein a memory element of OxRAM or CBRAM type is arranged at each interface between one of the metal portions and one of the first electrical interconnection lines, and each memory element comprises a first electrode arranged against said one of the first electrical interconnection lines, a second electrode arranged against said one of the metal portions, and a memory layer arranged between the first and second electrodes,
and wherein the first electrical interconnection lines, the metal portions and the memory elements are arranged in a same longitudinal plane parallel to the substrate of the memory device.

2. Memory device according to claim 1, wherein each memory element further comprises a portion of getter material arranged between the memory layer and one of the first and second electrodes.

3. Memory device according to claim 1, further comprising, in a second metallization level parallel to the first metallization level, second electrical interconnection lines parallel to one another and electrically coupled to the metal portions or to the first electrical interconnection lines.

4. Memory device according to claim 3, further comprising first electrically-conductive vias electrically coupling the second electrical interconnection lines to the metal portions or to the first electrical interconnection lines.

5. Memory device according to claim 3, wherein, when the second electrical interconnection lines are electrically coupled to the metal portions, the first electrical interconnection lines are source lines of the memory device and the second electrical interconnection lines are bit lines of the memory device.

6. Memory device according to claim 3, wherein the first metallization level is arranged between the second metallization level and the substrate of the memory device.

7. Memory device according to claim 6, wherein the substrate comprises a semiconductor layer in which are formed transistors, one of the source or drain electrodes of each of the transistors being electrically coupled to one of the first electrical interconnection lines or to one of the metal portions by a second electrically-conductive via extending between the semiconductor layer and said one of the first electrical interconnection lines or between the semiconductor layer and said one of the metal portions.

8. Memory device according to claim 7, comprising, in a third metallization level parallel to the first and second metallization levels and such that the first metallization level is arranged between the second and third metallization levels, third electrical interconnection lines parallel to one another and perpendicular to the first electrical interconnection lines, and wherein the third electrical interconnection lines are electrically coupled to the gates of the transistors.

9. Memory device according to claim 3, wherein each of the two neighboring first electrical interconnection lines is electrically coupled to memory elements which are electrically coupled to different second electrical interconnection lines.

10. Memory device according to claim 1, wherein the first electrical interconnection lines extend in a plane perpendicular to surfaces of larger dimensions of the memory layer and of the first and second electrodes.

11. Method of manufacturing a memory device comprising a substrate, the method comprising at least:
forming, in a first metallization level, of first electrical interconnection lines parallel to one another, and of metal portions parallel to one another and each electrically coupling two neighboring first electrical interconnection lines,
forming, at each interface between one of the metal portions and one of the first electrical interconnection lines, of a memory element of OxRAM or CBRAM type comprising a first electrode arranged against said one of the first electrical interconnection lines, a second electrode arranged against said one of the metal portions, and a memory layer arranged between the first and second electrodes,
and wherein the first electrical interconnection lines, the metal portions, and the memory elements are formed in the same longitudinal plane parallel to the substrate of the memory device.

12. Method according to claim 11, wherein the first electrical interconnection lines, the metal portions, and the memory elements are formed by implementing the following steps:
etching, into a first dielectric layer, of first trenches defining locations for the first electrical interconnection lines,
deposition of at least one first metallic material into the first trenches, forming the first electrodes of the memory elements, and of at least one second metallic material forming the first electrical interconnection lines,
etching, into the first dielectric layer, of first holes defining locations for the metal portions and the memory elements,
successive depositions of a plurality of materials into the first holes, forming the memory elements and the metal portions.

13. Method according to claim 11, further comprising, after the forming of the first electrical interconnection lines, of the metal portions, and of the memory elements:
deposition of at least one second dielectric layer on the first electrical interconnection lines, the metal portions, and the memory elements,
etching, through a first part of the thickness of the second dielectric layer, of second trenches parallel to one another and defining locations for second electrical interconnection lines,
etching, through a second part of the thickness of the second dielectric layer, under the second trenches and vertically in line with the metal portions or the first electrical interconnection lines, of second holes defining locations for first electrically-conductive vias,
deposition of at least another metallic material into the second holes and into the second trenches, forming the second electrical interconnection lines and the first electrically-conductive vias electrically coupling one of the second electrical interconnection lines to the metal portions or to the first electrical interconnection lines.

14. Method according to claim 11, further comprising, prior to the forming of the first electrical interconnection lines, of the metal portions, and of the memory cells, the forming, from a semiconductor layer of the substrate, of transistors, one of the source or drain electrodes of each of the transistors being electrically coupled to one of the first electrical interconnection lines or to one of the metal portions by a second electrically-conductive via extending between the semiconductor layer and said one of the first electrical interconnection lines or between the semiconductor layer and said one of the metal portions.

15. Method according to claim 14, wherein the forming of the transistors includes the forming of gates electrically coupled to third electrical interconnection lines parallel to one another and perpendicular to the first electrical interconnection lines.
